(19) United States
(12) Patent Application Publication
(10) Pub. No.: US 2025/0113700 A1
(43) Pub. Date: Apr. 3, 2025

(54) QUANTUM DOT IMAGE SENSOR DEVICES AND METHODS OF MANUFACTURING THE SAME

(71) Applicant: Adeia Semiconductor Bonding Technologies Inc., San Jose, CA (US)

(72) Inventors: Rajesh Katkar, Milpitas, CA (US); Belgacem Haba, Saratoga, CA (US); Cyprian Emeka Uzoh, San Jose, CA (US)

(21) Appl. No.: 18/532,332

(22) Filed: Dec. 7, 2023

Related U.S. Application Data
(60) Provisional application No. 63/541,569, filed on Sep. 29, 2023.

(51) Int. Cl. H10K 39/00; H01L 23/00; H01L 25/00; H01L 25/065; H01L 25/18; H10K 39/32

(52) U.S. Cl. CPC H10K 39/601; H01L 24/08; H01L 24/80; H01L 25/0657; H01L 25/18; H01L 25/50; H10K 39/32; H01L 2224/08145; H01L 2224/80895; H01L 2224/80896

(57) ABSTRACT

Conductive features of a device including quantum dots of a first substrate are bonded to conductive features of a second substrate. A quantum dot layer is formed on the first substrate having conductive features in a dielectric layer. Hybrid bonding of the first substrate to the second substrate is performed without use of an intervening adhesive to connect the first conductive features and the second conductive features.

### CROSS-REFERENCE TO RELATED APPLICATION

This application claims the benefit of U.S. Provisional Patent Application No. 63/541,569, filed Sep. 29, 2023, which is hereby incorporated by reference herein in its entirety.

### FIELD

The present disclosure relates to advanced packaging of semiconductor devices, and in particular, to hybrid bonding methods and device assemblies formed using the same.

### BACKGROUND

A problem for forming image sensor devices is that a photodiode layer may be constrained to having to be process compatible with complementary metal-oxide semiconductor (CMOS) devices. What is needed in the art are methods of manufacturing an optimized photodiode layer that is not burdened by process compatibility with CMOS devices.

### SUMMARY

Embodiments herein generally provide for quantum dot (QD) image sensor devices and methods of forming quantum dot image sensor devices. Generally, the methods include forming a quantum dot image sensor device by hybrid bonding a first substrate with quantum dot sensors to a second substrate with an image processor device. Advantageously, the method provides for processing of quantum dot materials into separate films to form bondable films, substrates, or wafers that enables a robust supply chain. For example, a first manufacturing facility may fabricate sensors with quantum dots in contact with electrodes that are reliably encapsulated for extended shelf life (shipping, storage at fabrication or assembly site, etc.) and engineered to reduce the impact of environmental exposure (e.g. oxidation, humidity, temperature fluctuations, etc.) to the quantum dots without creating a barrier to charge transport. A second manufacturing facility, such as a semiconductor foundry, may fabricate a read out circuit (e.g., a read out integrated circuit (ROIC)) or image processor device from a semiconductor foundry using well-established processes (e.g. complementary metal-oxide semiconductor (CMOS) process fabrication). An image sensor device can be formed by hybrid bonding the sensor with quantum dots to the image processor device. In this way, separate processing of the sensor with quantum dots and image processor device enables optimization of forming each component. For example, quantum dots can be processed and encapsulated in an environment advantageous for reducing the impact of oxidation and/or humidity, temperature fluctuations, etc. to quantum dots while the image processor device can be fabricated using an environment for well-known processes in a semiconductor foundry.

One general aspect includes a method of forming electrical connections between first and second substrates. The method includes forming a quantum dot layer on the first substrate, the first substrate having conductive features (e.g., bond pads) in a dielectric layer. The method further includes hybrid bonding the first substrate to the second substrate without use of an intervening adhesive to connect the conductive features of the first substrate to conductive features of the second substrate.

In some embodiments, the method comprises forming a sensor with quantum dots and hybrid bonding the sensor to an image processor device without use of an intervening adhesive to connect the conductive features of the sensor to conductive features of the image processor device. The sensor with quantum dots comprises a quantum dot layer and electrodes, and the sensor can be formed using various methods. In some embodiments, there may be multiple quantum dot layers.

In some embodiments, the method comprises forming a sensor with quantum dots with electrodes as conductive features that are bonded to conductive features of the processor device. The method comprises forming the sensor by depositing a quantum dot layer on a substrate, the substrate including a first dielectric layer and conductive features disposed in the first dielectric layer. Forming the sensor further comprises depositing a second dielectric layer on the quantum dot layer.

In some embodiments, the method comprises forming a sensor with quantum dots including an interconnect layer and conductive features where electrodes of the sensor are connected to the conductive features via interconnects in the interconnect layer.

In some embodiments, the method comprises forming a sensor by depositing a quantum dot layer on a first electrode of a substrate, the substrate comprising electrodes, an interconnect layer, and conductive features. The electrodes comprise a first electrode and a second electrode, and the conductive features comprise a first conductive feature and a second conductive feature. The first electrode and the second electrode are electrically connected to the first conductive feature and the second conductive feature, respectively via interconnects in the interconnect layer. Forming the sensor further comprises depositing a transparent conductive layer on the quantum dot layer and the second electrode, wherein the transparent conductive layer is electrically connected to the second electrode. Forming the sensor further comprises depositing a dielectric layer on the transparent conductive layer. The first electrode may be planar with a surface of the interconnect layer or may protrude from or may be recessed at a surface of the interconnect layer.

In some embodiments, the method comprises forming a sensor with planar or protruding electrodes from the surface of the interconnect layer. Forming the sensor comprises depositing a quantum dot layer on electrodes of a substrate, the substrate comprising the electrodes, an interconnect layer, and conductive features. The electrodes are electrically connected to the conductive features via interconnects in the interconnect layer. Forming the sensor further comprises depositing a dielectric layer on the quantum dot layer. In some embodiments, depositing a dielectric layer on the quantum dot layer may be optional. The electrodes may be planar with a surface of the interconnect layer or may protrude from or may be recessed at a surface of the interconnect layer.

In some embodiments, the method comprises forming a sensor in an opening of an interconnect layer with electrodes recessed from a surface of a first dielectric layer. Forming the sensor comprises forming a quantum dot layer on at least a portion of the electrodes of a substrate. The substrate comprises the first dielectric layer, the electrodes, an interconnect layer, and conductive features. The electrodes are recessed from a surface of the first dielectric layer, and the electrodes are electrically connected to the conductive features via interconnects in the interconnect layer. Forming the sensor further comprises depositing a second dielectric layer on the quantum dot layer. In some embodiments, depositing a second dielectric layer on the quantum dot layer may be optional.

In some embodiments, the method comprises forming a sensor with a transparent conductive layer in an opening of a substrate. Forming the sensor comprises depositing a quantum dot layer on a transparent conductive layer in an opening of the substrate. Forming the sensor further comprises depositing a dielectric layer on the substrate, the dielectric layer having a first opening that exposes a portion of the quantum dot layer and a second opening that exposes a portion of the transparent conductive layer. Forming the sensor further comprises depositing a conductive layer in the first opening and the second opening to form conductive features comprising a first conductive feature and a second conductive feature, respectively. The second conductive feature is electrically connected to the transparent conductive layer.

In some embodiments, the method comprises forming a sensor in an opening of a substrate. Forming the sensor comprises depositing a quantum dot layer in an opening of a substrate. Forming the sensor further comprises depositing a dielectric layer on the substrate that exposes portions of the quantum dot layer. Forming the sensor further comprises depositing conductive features on the substrate.

In some embodiments, depositing the quantum dot layer is performed by ink jet printing. In some embodiments, depositing the quantum dot layer is performed by spin coating. In some embodiments, depositing the quantum dot layer is performed by spin coating the quantum dot layer and patterning the spin coated quantum dot layer.

In some embodiments, the conductive features of the sensor comprise pairs of electrodes. The depositing the quantum dot layer may be performed by spin coating to form a continuous quantum dot layer. A spacing between a first pair of electrodes to a second pair of electrodes may be greater than about two times a thickness of the quantum dot layer.

In some embodiments, conductive features of the sensor comprise a plurality of first electrodes and second electrodes in an array.

Another general aspect includes a device assembly comprising a first device bonded to a second device.

### BRIEF DESCRIPTION OF THE DRAWINGS

The above and other objects and advantages of the disclosure will be apparent upon consideration of the following detailed description, taken in conjunction with the accompanying drawings.

FIG. 1A schematically illustrates a method of hybrid bonding a sensor with a patterned quantum dot layer to an image processor device, according to some embodiments;

FIG. 1B schematically illustrates a method of hybrid bonding a sensor with a continuous quantum dot layer to an image processor device, according to some embodiments;

FIG. 1C schematically illustrates a method of forming sensors with a patterned quantum dot layer, according to some embodiments;

FIG. 1D schematically illustrates a method of forming sensors with a continuous quantum dot layer, according to some embodiments;

FIG. 1E schematically illustrates a method of hybrid bonding sensors with a patterned quantum dot layer to an image processor device, according to some embodiments;

FIG. 1F schematically illustrates a method of hybrid bonding sensors with a continuous quantum dot layer to an image processor device, according to some embodiments;

FIG. 2A schematically illustrates example sensors with patterned quantum dot layer on an interconnect layer, according to some embodiments;

FIG. 2B schematically illustrate example sensors with continuous quantum dot layer on an interconnect layer, according to some embodiments;

FIG. 2C schematically illustrates a method of forming a sensor with a patterned quantum dot layer and transparent electrode, according to some embodiments;

FIG. 2D schematically illustrates a method of hybrid bonding a sensor with a patterned quantum dot layer and transparent electrode to an image processor device, according to some embodiments;

FIG. 2E schematically illustrate example sensors with a patterned quantum dot layer on a semiconductor layer, according to some embodiments;

FIG. 2F schematically illustrate example sensors with a continuous quantum dot layer on a semiconductor layer, according to some embodiments;

FIG. 3 schematically illustrates example configurations of electrodes, according to some embodiments;

FIG. 4A schematically illustrates an example of a sensor with a patterned quantum dot layer and a protruding electrode, according to some embodiments;

FIG. 4B schematically illustrates a method of hybrid bonding a sensor with a patterned quantum dot layer and a protruding electrode to an image processor device, according to some embodiments;

FIG. 4C schematically illustrates an example of a sensor with a patterned quantum dot layer and protruding electrodes, according to some embodiments;

FIG. 4D schematically illustrates a method of hybrid bonding a sensor with a patterned quantum dot layer and protruding electrodes to an image processor device, according to some embodiments;

FIG. 5A schematically illustrates a method of forming a sensor with a patterned quantum dot layer and a pair of recessed electrodes, according to some embodiments;

FIG. 5B schematically illustrates a method of hybrid bonding a sensor with a patterned quantum dot layer and a pair of recessed electrodes to an image processor device, according to some embodiments;

FIG. 6A schematically illustrates a method of forming a sensor with a patterned quantum dot layer and transparent electrode, according to some embodiments;

FIG. 6B schematically illustrates a method of hybrid bonding a sensor with a patterned quantum dot layer and transparent electrode to an image processor device, according to some embodiments;

FIG. 7A schematically illustrates a method of forming a sensor with a patterned quantum dot layer, according to some embodiments;

FIG. 7B schematically illustrates a method of hybrid bonding a sensor with a patterned quantum dot layer to an image processor device, according to some embodiments;

FIG. 8A schematically illustrates an image sensor device with color filters, according to some embodiments; and

FIG. 8B schematically illustrates an image sensor device with a patterned quantum dot layer with different quantum dots, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Quantum dot materials are an emerging technology for use in sensor device. For example, quantum dot materials (e.g., PbS, CdS, CdSe, ZiSe) may have a tunable absorption spectrum to provide image sensing across a range of wavelengths. The material of the quantum dot and the size of the particles (e.g., quantum dots) can be adjusted to absorb any wavelength of light (e.g. visible and infrared spectrum). Different materials and particle sizes could be further mixed to adjust to wider band of wavelengths. Quantum dot material may be applied by inkjet printing or spin coating from a colloidal solution. However, fabrication of quantum dot materials may be uncommon to CMOS fabs (e.g., where an image processor device may be fabricated), and the durability of quantum dot material may be affected by exposure to heat, oxygen, and water vapor. For example, quantum dots may oxidize in air, causing imperfections and changes to sensor properties (e.g., reduced sensitivity, increased noise, slower response time). For use of quantum dots in image sensors, quantum dots may not be individually sealed off in a solution, e.g. encapsulant or polymer, to prevent or reduce oxidation because it may prevent electron transport to electrodes to be counted. In some embodiments, sealing off quantum dots in a solution may comprise a curing process. Encapsulating quantum dots would be preferably done without creating a barrier for photo-generated charge transport.

Embodiments herein provide for methods to process quantum dots to form bondable substrates. Processing quantum dots to form bondable substrates (e.g., including sensors with quantum dots) enable separate processing of quantum dot materials and materials from more conventional processes. For example, quantum dot materials can be processed to form a sensor device in which quantum dots can be encapsulated or engineered to reduce the impact of oxidation, humidity, temperature and other environmental exposure without creating a barrier for charge transport. An image processor device (e.g., ROIC) may be processed in a separate fab for more conventional processes (e.g., semiconductor foundry). In some embodiments, photodiodes or bondable substrates with quantum dots can be manufactured at temperatures that exceed the thermal budget of a control device (e.g., device processed in a semiconductor foundry). The sensor and image processor device can be bonded to form an image sensor device. Separating the processes for forming a sensor with quantum dots and for forming an image processor device enables a more robust supply chain for optimizing separate components with different processes rather than having a manufacturer generate an integrated component by combining the processing of the sensor and quantum dot materials on the image processor device.

As described below, semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein relate to bonded structures in which two or more elements are directly bonded to one another without an intervening adhesive (referred to herein as “direct bonding”, or “directly bonded”). In some embodiments, direct bonding can involve the bonding of a single material on the first of the two or more elements and a single material on a second one of the two more elements, where the single materials on the different elements may or may not be the same. Direct bonding can also involve bonding of multiple materials on one element to multiple materials on the other element (e.g., hybrid bonding). As used herein, the term “hybrid bonding” refers to a species of direct bonding in which both i) nonconductive features directly bond to nonconductive features, and ii) conductive features directly bond to conductive features.

The hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N2, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes “semiconductor substrates” that provide a supporting material upon which elements of a semiconductor device are fabricated or attached, and any material layers, features, electronic devices, and/or passive devices formed thereon, therein, or therethrough. For ease of description elements, features, sensors, and devices formed therefrom are referred to in the singular or plural but should be understood to describe both singular and plural, e.g., one or more, unless otherwise noted.

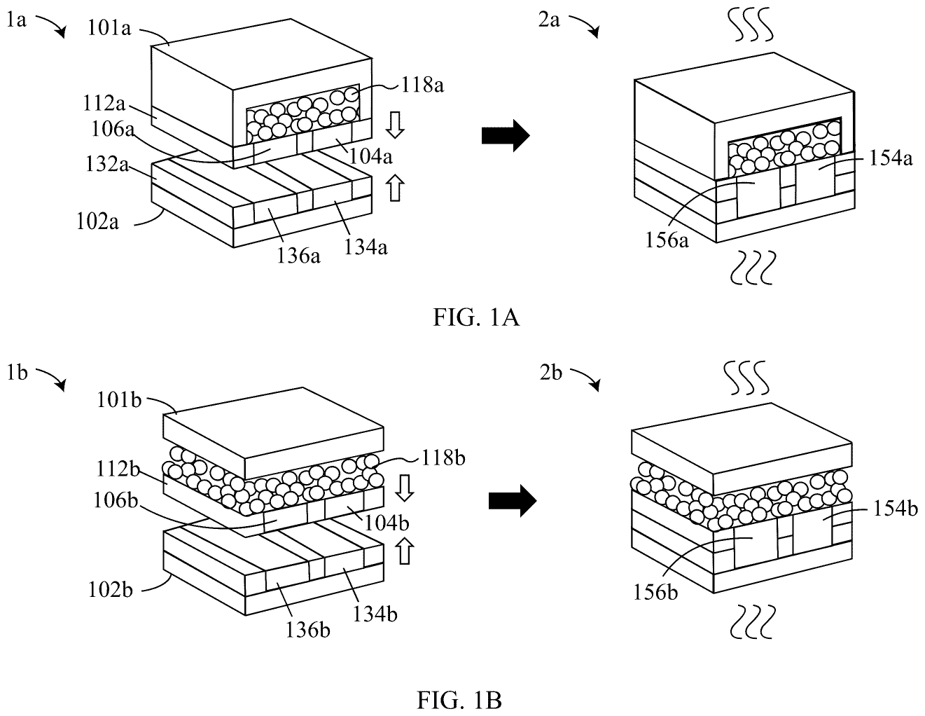

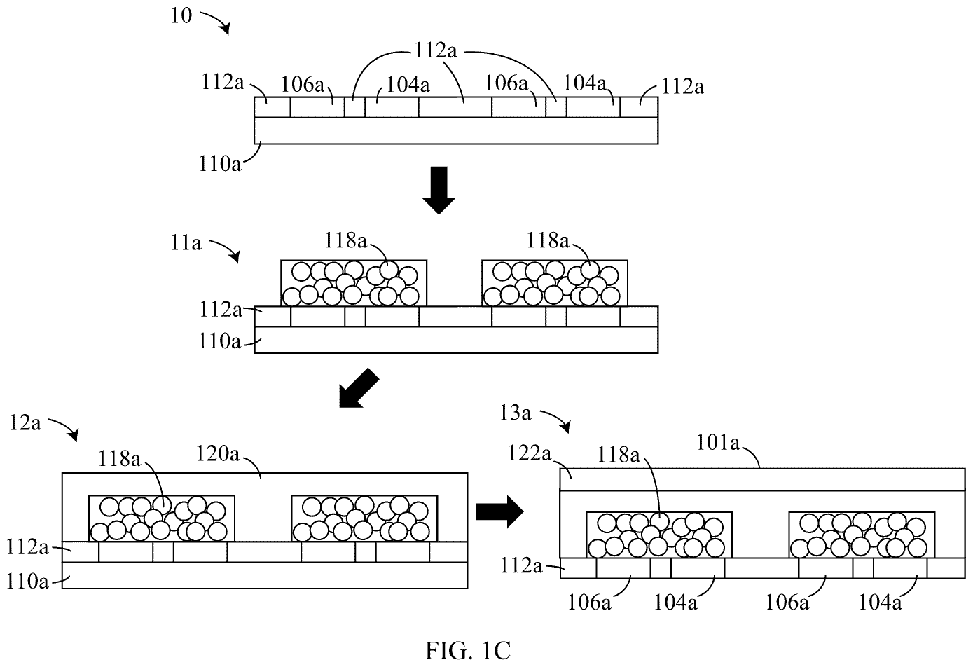

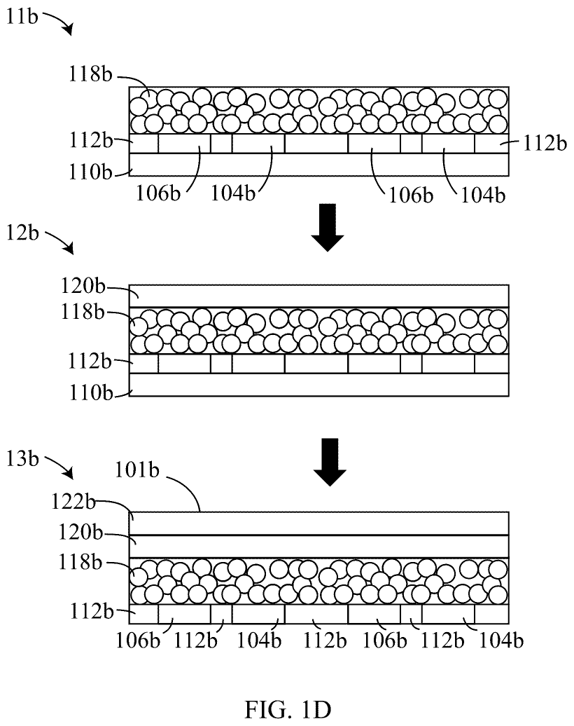

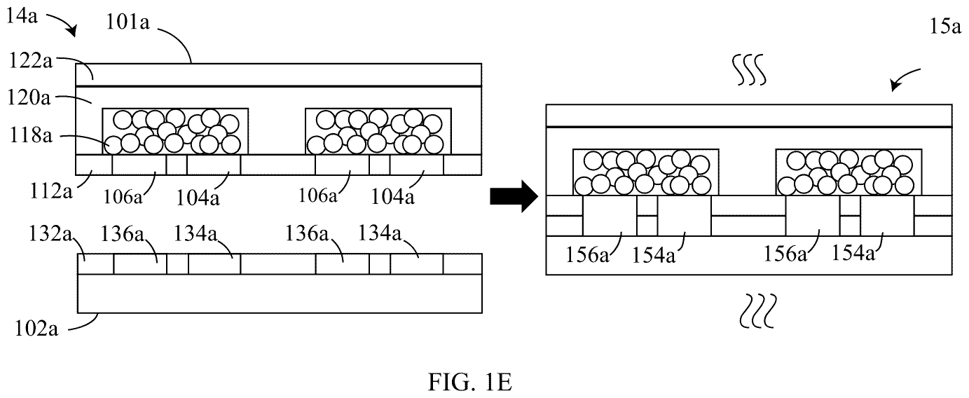

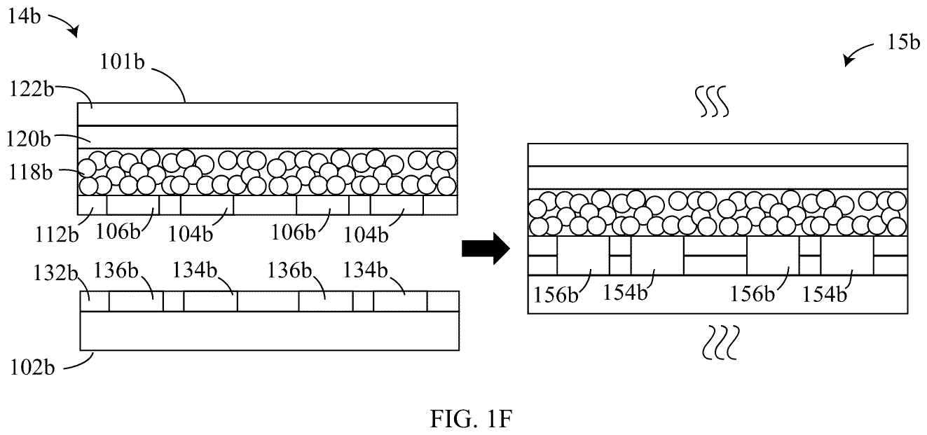

FIG. 1A schematically illustrates a method of forming a quantum dot image sensor device, according to some embodiments. Generally, the method includes forming light sensors, such as photodiodes, each having a patterned quantum dot layer, such as the sensors 101a described below in FIG. 1C, and hybrid bonding the sensor 101a with a patterned quantum dot layer to an image processor device 102a described below in FIG. 1E. At block 1a, the method includes aligning the respective conductive features 104a and 106a of the sensor 101a to the conductive features 134a and 136a of the image processor device 102a and contacting the sensor 101a and the image processor device 102a. In some embodiments, contacting the sensor 101a and the image processor device 102a may be performed at ambient temperatures. Here, contacting the sensor 101a and the image processor device 102a forms a workpiece where the sensor 101a and the image processor device 102a are attached to one another through direct bonds formed between the dielectric layers 112a and 132a without the use of an intervening adhesive. At block 2a, the method includes heating the workpiece to a processing temperature between about 50° C. to about 150° C. or more, or of about 150° C. or more, such as about 250° C. or more, or about 300° C. or more, to form direct interconnects 154a and 156a via hybrid bonding of the conductive features 104a and 106a of the sensor 101a to conductive features 134a and 136a of the image processor device 102a. For example, hybrid bonding may comprise directly bonding the conductive features 104a and 106a of the sensor 101a to the conductive features 134a and 136a of the image processor device 102a.

FIG. 1B schematically illustrates a method of forming a quantum dot image sensor device, according to another embodiment. Generally, the method includes forming light sensors, such as photodiodes having a continuous quantum dot layer, such as the sensors 101b described below in FIG. 1D, and hybrid bonding the sensors 101b with a continuous quantum dot layer to an image processor device 102b described below in FIG. 1F. At block 1b, the method includes aligning the respective conductive features 104b and 106b of the sensor 101b to the conductive features 134b and 136b of the image processor device 102b and contacting the sensor 101b and the image processor device 102b. In some embodiments, contacting the sensor 101b and the image processor device 102b may be performed at ambient temperatures. Here, contacting the sensor 101b and image processor device 102b forms a workpiece where the sensor 101b and the image processor device 102b are attached to one another through direct bonds formed between the dielectric layers 112b and 132b without the use of an intervening adhesive. At block 2b, the method includes heating the workpiece to a processing temperature between about 50° C. to about 150° C. or more, or of about 150° C. or more, such as about 250° C. or more, or about 300° C. or more, to form direct interconnects 154b and 156b via hybrid bonding of the conductive features 104b and 106b of the sensor 101b to conductive features 134b and 136b of the image processor device 102b. For example, hybrid bonding may comprise directly bonding the conductive features 104b and 106b of the sensor 101a to the conductive features 134b and 136b of the image processor device 102b.

FIG. 1C schematically illustrates a method of forming sensors 101a with a patterned quantum dot layer, according to some embodiments. In some embodiments, the method comprises forming sensors 101a with quantum dots with electrodes as conductive features 104a and 106a that are bonded to conductive features 134a and 136a of the image processor device 102a. The method comprises forming the sensor 101a by depositing a quantum dot layer 118a on a substrate, the substrate comprising a first dielectric layer 112a and conductive features 104a and 106a disposed in the first dielectric layer 112a.

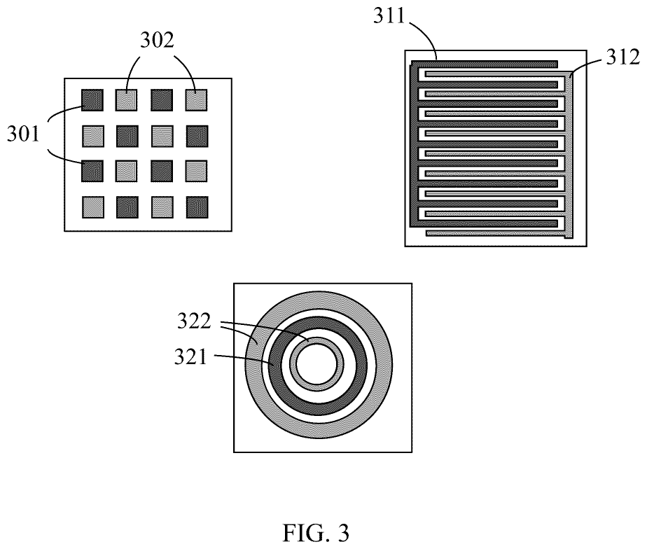

At block 10, a substrate comprises a first dielectric layer 112a, (e.g., SiO2) and conductive features 104a and 106a disposed in the first dielectric layer 112a. The conductive features 104a and 106a may be formed of a conductive material (e.g., copper) and may be arranged in various shapes, sizes and numbers (e.g., as described in reference to FIG. 3). The substrate may be attached to a temporary carrier 110a.

In some embodiments, an optional electron transport layer (ETL, e.g., TiOx, ZnO) or a hole transport layer (e.g., p-type polymer) may be deposited between the conductive features 104a and 106a and the quantum dot layer 118a to improve carrier transport and injection. In some embodiments, a graphene sheet or layer may be formed between the electrodes and the quantum dot layer to improve carrier transport. For example, a graphene sheet may be formed between the electrodes (e.g., conductive features 104a and 106a) and the quantum dot layer (e.g., quantum dot layer 118a).

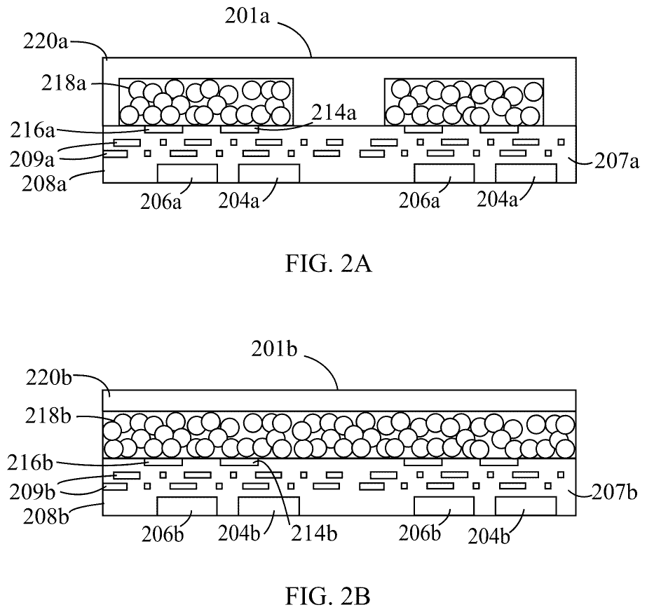

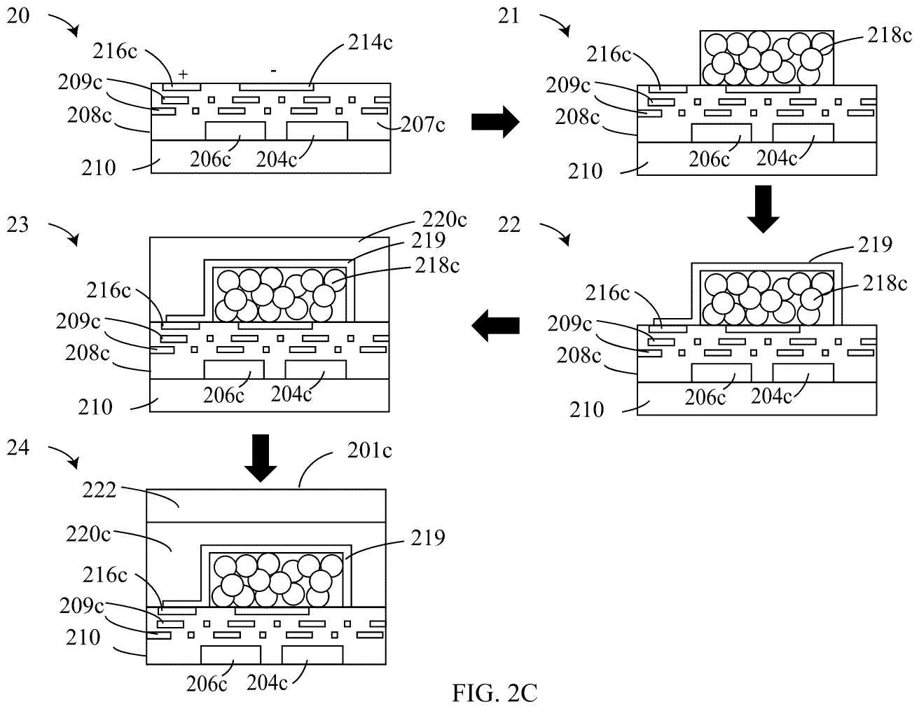

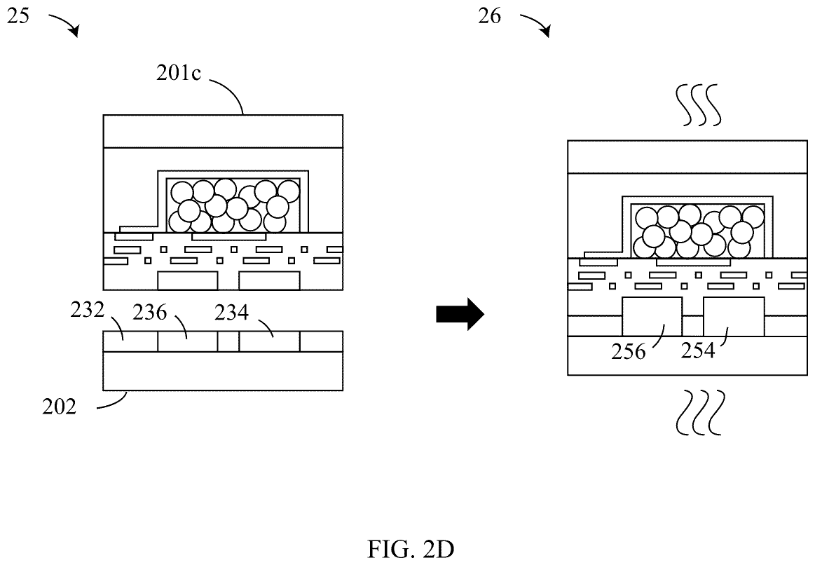

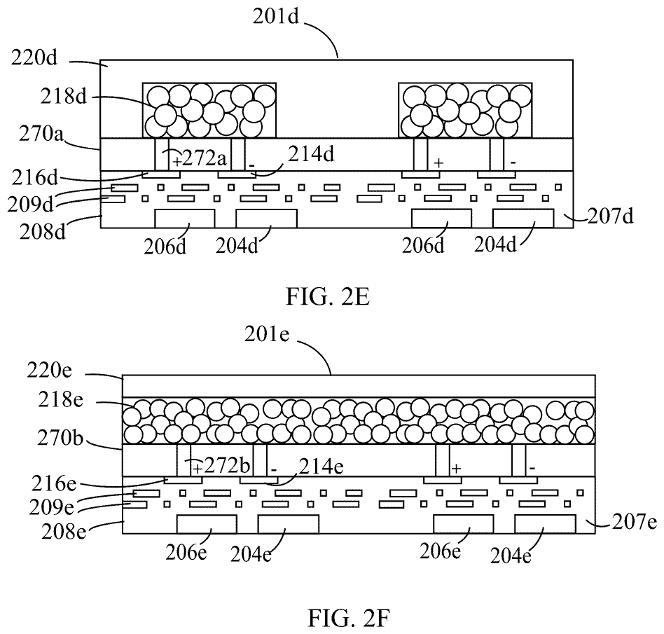

In some other embodiments, a quantum dot layer or a patterned quantum dot layer is deposited on top of a semiconductor layer providing pixel transistors between the quantum dot layer and the conductive features 104a and 106a, such as embodiments described below in FIGS. 2E and 2F with conductive features 204d, 204e and 206d, 206e. The quantum dot layer acts as the photodiodes (i.e. convert photons to electrical signals) and pixel transistors on the semiconductor layer (e.g. silicon) controls the electrical signals. The charge created by a photo-detector is converted to a voltage signal and passed on to the output amplifier through an array of row-select and column-select switches. Furthermore, an analog to digital convertor (ADC) may be formed on the semiconductor layer to digitize the amplified signal. To perform readout, the pixel values of a given row are transferred in parallel to a set of storage capacitors and then, these transferred pixel values are read out sequentially. While the quantum dot layer(s) only perform the photodetection function, the semiconductor layer(s) perform the rest of the operation. The semiconductor layer may provide the pixel circuits comprising amp transistors, select transistors, reset transistors, signal lines, ADC, pixel select switches (or row/column selects), memory blocks, capacitors, etc. to form an image sensor circuit with the quantum dot sensor layer.

The pixel sensor architecture may be one of several types. In an active-pixel sensor (APS) architecture, each pixel location contains not only the photodiode but also an amplifier. A simpler architecture like passive-pixel sensor (PPS) may also be implemented within the semiconductor layer that does not integrate an amplifier into each pixel. In a digital-pixel sensor (DPS) device architecture, each pixel may have its own analog-to-digital converter and memory block which allows the digital values proportional to light intensity.

In some other embodiments, pixel transistors may be a part of image processor device 102a. In some embodiments, the pixel transistors may be part of image processor device 102b.

At block 11a, the method includes depositing a quantum dot layer 118a on the substrate. The quantum dot layer 118a is patterned. The quantum dot layer 118a may be deposited by ink jet printing in which the specific amount of quantum dot material (e.g. size, shape, volume, material type, etc.) may be directly deposited to pixel locations to form individual pixel. The quantum dot layer 118a may also be deposited by spin coating to form a spin coated quantum dot layer and patterning the spin coated quantum dot layer to effectively form separate pixels. For example, a spin-coated quantum dot layer may be photolithographically patterned. In some embodiments, the quantum dot layer 118a is cured. For example, a quantum dot solution (e.g., colloidal quantum dot solution) may be used to form the quantum dot layer 118a and cured. In some embodiments, the quantum dot layer 118a comprises quantum dots. In some embodiments, the quantum dot layer 118a comprises quantum dots in a transparent insulating material. For example, the quantum dot layer 118a may comprise quantum dots in a polymer.

Although block 11a depicts the quantum dots deposited directly on the first dielectric layer 112a and conductive features 104a and 106a disposed in the first dielectric layer 112, one or more dielectric and metal layers may also be formed on top of first dielectric layer 112a and conductive features 104a and 106a (e.g., as shown in FIGS. 2A and 2B with conductive features 204a, 204b and 206a, 206b), electrodes may be formed at the top surface (e.g. as depicted in FIG. 3), and the quantum dots may be deposited on those electrodes. In other embodiments, pixel transistors may be formed on a separate semiconductor layer between the top electrode layer and the quantum dots layer and the electrodes may be extended through the semiconductor layer (e.g. using through silicon vias and plugs) to form the contacts between the quantum dots and the electrodes, such as embodiments described below in FIGS. 2E and 2F. In some embodiments, electrodes may be formed of a conductive material (e.g., metal, transparent conductive oxide, etc.).

At block 12a, the method includes depositing a second dielectric layer 120a on the quantum dot layer 118a. The second dielectric layer 120a may serve as a barrier or encapsulation layer to protect the quantum dots from oxidation. The second dielectric layer 120a may comprise an oxide material. The second dielectric layer 120a may comprise a material transparent to wavelengths to be detected by the sensor 101a (e.g., infrared (IR), near IR (NIR), short wave IR (SWIR), visible, or any application relevant wavelength range). For example, if the sensor 101a detects short wave infrared (SWIR) wavelengths, the second dielectric layer 120a may be transparent to wavelengths of the SWIR range. If the sensor 101a detects a visible range, the second dielectric layer 120a may be transparent to wavelengths in the visible range. In some embodiments, the second dielectric layer 120a may comprise two or more dielectric layers. In other embodiments, additional sealing layer may be deposited (e.g. for further mechanical or environmental protection). For example, the second dielectric layers may comprise one or more layers of silicon oxide, silicon nitride, etc. In some embodiments, the dielectric layers may be polished after deposition to form non-wavy (e.g., smooth) top surface for further deposition of other layers or devices (e.g. polymer lenses, color filters, infrared filters, etc.). In some embodiments, other layers or devices may be formed overlaying second dielectric layer(s) 120a.

In some embodiments, a sealing/barrier film is used in place of the second dielectric layer 120a. The sealing film may comprise a conductive oxide material (e.g., indium tin oxide, indium, zinc, or tin oxide), an oxide material (e.g., aluminum oxide, silicon dioxide), a polymer material, or some combination thereof. For example, the sealing film may comprise alternating inorganic and polymer layers and may provide additional protection against environmental exposure (e.g. oxidation, humidity, etc.) and/or mechanical protection. In some embodiments, the second dielectric layer 120a or sealing/barrier film is optional. For example, a quantum dot layer 118a may be quantum dots formed in a transparent insulating material, and the transparent insulating material may protect the quantum dots from oxidation. For example, the transparent insulating material may be a polymer.

At block 13a, the method includes attaching the second dielectric layer 120a (or sealing layer above it) to a second carrier 122a and releasing the temporary carrier 110a (first carrier). In some embodiments, the second dielectric layer 120a is polished before attaching to the second carrier 122a. The second carrier 122a may be a silicon substrate, glass substrate or another suitable temporary carrier or substrate. In some embodiments, the conductive features 104a and 106a and/or the first dielectric layer 112a are chemically mechanically polished (CMP). The sensor 101a comprises the substrate comprising the first dielectric layer 112a and the conductive features 104a and 106a disposed in the first dielectric layer 112a, quantum dot layer 118a that is patterned, the second dielectric layer 120a, and carrier 122a. The sensor 101a may additionally comprise a pixel transistor layer.

FIG. 1D schematically illustrates a method of forming a sensor 101b with a continuous quantum dot layer, according to some embodiments. Block 11b in FIG. 1D may follow from block 10 in FIG. 1C, and the substrate in block 11b may correspond to substrate in block 10. The substrate in block 11b comprises a first dielectric layer 112b, (e.g., SiO2) and conductive features 104b and 106b disposed in the first dielectric layer 112b. The conductive features 104b and 106b may be formed of a conductive material (e.g., copper) and may be arranged in various shapes, sizes and numbers (e.g., as described in reference to FIG. 3). The substrate may be attached to a temporary carrier 110b.

In some embodiments, a separate semiconductor layer providing pixel transistors and image sensor circuits may be provided between the conductive features 104b and 106b and the quantum dot layer 118b (e.g., as shown in FIG. 2F with conductive features 204e and 206e and quantum dot layer 218e). In some embodiments, an optional electron transport layer (e.g., TiOx, ZnO) or a hole transport layer (e.g., p-type polymer) may be deposited between the conductive features 104b and 106b and the quantum dot layer 118b to improve carrier transport and injection. In some embodiments, a graphene sheet or layer may be formed between the electrodes and the quantum dot layer to improve carrier transport. For example, a graphene sheet may be formed between the electrodes (e.g., conductive features 104b and 106b) and the quantum dot layer (e.g., quantum dot layer 118b).

In block 11b, the method includes depositing a quantum dot layer 118b on the substrate. The quantum dot layer 118b is continuous and may be deposited by spin coating. In some embodiments, the quantum dot layer 118b is cured. For example, depositing the quantum dot layer 118b may comprise spin coating a quantum dot solution and then curing the spin-coated quantum dot layer. In some embodiments, the quantum dot layer 118b comprises quantum dots. In some embodiments, the quantum dot layer 118b comprises quantum dots in a transparent insulating material. For example, the quantum dot layer 118b may comprise quantum dots in a polymer.

At block 12b, a second dielectric layer 120b is deposited on the quantum dot layer 118b. The second dielectric layer 120b may be similar to the second dielectric layer 120a in FIG. 1C and may be formed using a same or a substantially similar process, except it is deposited over a quantum dot layer 118b that is continuous instead of a quantum dot layer 118a that is patterned. In some embodiments, the second dielectric layer 120b or sealing film is optional. In some embodiments, second dielectric layer 120b may comprise two or more dielectric layers. In other embodiments, additional sealing layer may be deposited (e.g. for further mechanical or environmental protection). For example, the second dielectric layers may comprise one or more layers of silicon oxide, silicon nitride, etc. In some embodiments, the dielectric layers may be polished after deposition to form non-wavy (e.g., smooth) top surface for further deposition of other layers or devices (e.g. polymer lenses, color filters, infrared filters, etc.). In some embodiments, other layers or devices may be formed overlaying second dielectric layer(s) 120b.

At block 13b, the method includes attaching the second dielectric layer 120b (or sealing layer above it) to a second carrier 122b and releasing the temporary carrier 110b (first carrier). The sensor 101b comprises the substrate comprising the first dielectric layer 112b and the conductive features 104b and 106b disposed in the first dielectric layer 112b, quantum dot layer 118b, the second dielectric layer 120b, and carrier 122b. In some embodiments, the second dielectric layer 120b is polished before attaching to the second carrier 122b. In some embodiments, the second dielectric layer 120b and/or the second carrier 122b is optional, and the sensor 101b may comprise the substrate and the quantum dot layer 118b, the substrate comprising the dielectric layer 112b and the conductive features 104b and 106b disposed in the dielectric layer 112b.

In some embodiments, the conductive features 104b and 106b comprise pairs of electrodes, and a spacing between a first pair of electrodes to a second pair of electrodes (e.g., pairs of conductive features 104b and 106b) is greater than about two times a thickness of the quantum dot layer 118b. For example, minimal or no cross-talk may occur between sensor pixels if the pitch between pairs of pads is greater than two times the film thickness of the quantum dot layer 118b. The distance between pairs of neighboring electrodes (e.g., pairs of conductive features 104b and 106b) may be about a micron or 1 or more microns apart. The thickness of the quantum dot layer 118b may be 10 nanometers, 10 or more nanometers, less than about 100 nanometers, or about 50-500 nanometers. Electrons generated by quantum dots in the quantum dot layer 118b may be collected by the closest electrode pair, and would not be collected on an adjacent pair of electrodes more than a micron away.

FIG. 1E schematically illustrates a method of hybrid bonding a sensor 101a with a patterned quantum dot layer to an image processor device 102a, according to some embodiments. The method at FIG. 1E is the same as the method at FIG. 1A. For example, blocks 14a and 15a of FIG. 1E is the same or similar to blocks 1a and 2a of FIG. 1A, respectively. Blocks 14a and 15a are shown from a perspective of a side view and show two sensor pixels, whereas blocks 1a and 2a are shown from a 3D perspective and show one sensor pixel. Although one sensor pixel or two sensor pixels are shown in various embodiments of this disclosure, there may be any suitable number of sensor pixels (e.g., 3 or more, e.g., thousands of pixels, or millions of pixels).

FIG. 1F schematically illustrates a method of hybrid bonding a sensor 101b with a continuous quantum dot layer to an image processor device 102b, according to some embodiments. The method shown at FIG. 1F is the same as the method at FIG. 1B. For example, blocks 14b and 15b of FIG. 1E is the same or similar to blocks 1b and 2b of FIG. 1, respectively. Blocks 14b and 15b are shown from a perspective of a side view and show two sensor pixels, whereas blocks 1b and 2b are shown from a 3D perspective and show one sensor pixel.

FIG. 2A schematically illustrates an example of sensors 201a with a patterned quantum dot layer 218a on an interconnect layer 208a, according to some embodiments. In some embodiments, conductive features 204a and 206a of FIG. 2A may correspond to conductive features 104a and 106a formed in a first dielectric layer 112a of block 10 of FIG. 1C, except that one or more dielectric and metal layers are formed on top of the first dielectric layer 112a and conductive features 104a and 106a. For example, a bottom portion of dielectric material 207a of interconnect layer 208a may correspond to first dielectric layer 112a of FIG. 1C and an upper portion of dielectric material 207a (e.g., above the conductive features 204a and 206a) may correspond to one or more dielectric layers on top of first dielectric layer 112a of FIG. 1C, interconnects 209a may correspond to one or more metal layers, and electrodes 214a and 216a correspond to electrodes formed at the top surface of the interconnect layer 208a of FIG. 2A (e.g., corresponding to electrodes 301 and 302, 311 and 312, or 321 and 322 as depicted in FIG. 3). In some embodiments, interconnects 209a may be transparent. In some embodiments, interconnects 209a may comprise a transparent conductive material (e.g., transparent conductive oxide). In some embodiments, interconnects 209a may not be transparent.

The sensors 201a may be formed using a similar process to those described in blocks 11a-13a of FIG. 1C, except that instead of using the substrate shown in block 10 of FIG. 1C, a substrate with an interconnect layer 208a is used. The substrate may comprise electrodes 214a and 216a, an interconnect layer or redistribution layer 208a, and conductive features 204a and 206a. Although not shown, the substrate may be attached to a temporary carrier, which may be another substrate (e.g., glass or a semiconductor wafer, corresponding to 110a of block 10). The interconnect layer 208a may comprise interconnects 209a disposed in an insulating material 207a (e.g., dielectric material). The first electrode 214a and the second electrode 216a are electrically connected to conductive features 204a and 206a, respectively, via interconnects 209a in the interconnect layer 208a. In some embodiments, the first electrode 214a is a negative electrode and the second electrode 216a is a positive electrode. In some embodiments, the first electrode 214a and the second electrode 216a are planar to a surface of the interconnect layer 208a. In some other embodiments, the first electrode 214a and the second electrode 216a protrude from or be recessed at the interconnect layer 208a. The patterned quantum dot layer 218a may be similar to patterned quantum dot layer 118a, and the dielectric layer 220a may be similar to dielectric layer 120a.

FIG. 2B schematically illustrates an example of sensors 201b with a continuous quantum dot layer 218b on an interconnect layer 208b, according to some embodiments. In some embodiments, conductive features 204b and 206b, interconnect layer 208b, interconnects 209b, insulating material 207b, and first electrode 214b and second electrode 216b of FIG. 2B correspond to conductive features 204a and 206a, interconnect layer 208a, interconnects 209a, insulating material 207a, and first electrode 214a and second electrode 216a of FIG. 2A.

The sensors 201b may be formed using a similar process to those described in blocks 11b-13b of FIG. 1D, except that instead of using a substrate corresponding to one shown in block 10 of FIG. 1C, a substrate with an interconnect layer 208b is used. The substrate may comprise electrodes 214b and 216b, an interconnect layer or redistribution layer 208b, and conductive features 204b and 206b. Although not shown, the substrate may be attached to a temporary carrier, which may be another substrate (e.g., glass or a semiconductor wafer, corresponding to 110a of block 10). The interconnect layer 208b may comprise interconnects 209b disposed in an insulating material 207b (e.g., dielectric material). The first electrode 214b and the second electrode 216b are electrically connected to conductive features 204b and 206b, respectively, via interconnects 209b in the interconnect layer 208b. In some embodiments, the first electrode 214b is a negative electrode and the second electrode 216b is a positive electrode. In some embodiments, the first electrode 214b and the second electrode 216b are planar to a surface of the interconnect layer 208b. In some other embodiments, the first electrode 214b and the second electrode 216b are protruded from or recessed at a surface of the interconnect layer 208b. The continuous quantum dot layer 218b may be similar to continuous quantum dot layer 218b, and the dielectric layer 220b may be similar to dielectric layer 120b.In some embodiments, the electrodes 214b and 216b comprise pairs of electrodes, and a spacing between a first pair of electrodes to a second pair of electrodes (e.g., pairs of electrodes 214b and 216b) is greater than about two times a thickness of the quantum dot layer 218b. For example, minimal or no cross-talk may occur between sensor pixels if the pitch between pairs of electrodes is greater than two times the film thickness of the quantum dot layer 218b. The distance between pairs of neighboring electrodes (e.g., pairs of electrodes 214b and 216b) may be about a micron or 1 or more microns apart. The thickness of the quantum dot layer 218b may be 10 nanometers, 10 or more nanometers, less than about 100 nanometers, or about 50-500 nanometers. Electrons generated by quantum dots in the quantum dot layer 218b may be collected by the closest electrode pair (e.g., pair of electrodes 214b and 216b), and would not be collected on an adjacent pair of electrodes more than a micron away.

FIG. 2C schematically illustrates another method of forming a sensor 201c with a patterned quantum dot layer 218c and transparent electrode 219, according to some embodiments. In some embodiments, conductive features 204c and 206c, interconnect layer 208c, interconnects 209c, insulating material 207c, and first electrode 214c and second electrode 216c of FIG. 2C correspond to conductive features 204a and 206a, interconnect layer 208a, interconnects 209a, insulating material 207a, and first electrode 214a and second electrode 216a of FIG. 2A. At block 20, a substrate comprises electrodes 214c and 216c, an interconnect layer or redistribution layer 208c, and conductive features 204c and 206c. The substrate is attached to a temporary carrier 210. The temporary carrier 210 may be another substrate (e.g., glass or a semiconductor wafer). The interconnect layer 208c may comprise interconnects 209c disposed in an insulating material 207c. The first electrode 214c and the second electrode 216c are electrically connected to conductive features 204c and 206c, respectively, via interconnects 209c in the interconnect layer 208c. In some embodiments, the first electrode 214c is a negative electrode and the second electrode 216c is a positive electrode. In some embodiments, the first electrode 214c and the second electrode 216c are planar to a surface of the interconnect layer 208c. In some other embodiments, the first electrode 214c and the second electrode 216c are protruded from or recessed at the top surface of the interconnect layer 208c.

At block 21, the method includes depositing a quantum dot layer 218c on a first electrode 214c of the substrate. In some embodiments, the quantum dot layer 218c is formed using the same or a substantially similar process to those described for forming the quantum dot layer 118a in block 11a in FIG. 1C. The quantum dot layer 218c may be deposited by ink jet printing in which the specific amount of quantum dot material (e.g. size, shape, volume, material type, etc.) may be directly deposited to pixel locations to form individual pixels. The quantum dot layer 218c may alternatively be deposited by spin coating to form a spin coated quantum dot layer and then patterning the spin coated quantum dot layer to effectively form separate pixels on top electrodes 214c and 216c. For example, a spin-coated quantum dot layer may be photolithographically patterned. In some embodiments, the quantum dot layer 218c is formed on the first electrode 214c and not on the second electrode 216c.

At block 22, the method includes depositing a transparent conductive layer 219 on the quantum dot layer 218c and the second electrode 216c. The transparent electrode 219 is patterned. For example, the transparent conductive layer 219 may be deposited and patterned (e.g., via photolithography). As another example, the transparent conductive layer 219 may be patterned when deposited (e.g., via a shadow mask). The transparent conductive layer 219 is electrically connected to the second electrode 216c, and the transparent conductive layer 219 may be referred to as an electrode or a top electrode of the sensor 201c. In some embodiments, the transparent conductive layer 219 comprises a transparent conductive oxide material (e.g., ITO).

In some embodiments, an optional electron transport layer (e.g., TiOx, ZnO) and/or a hole transport layer (e.g., p-type polymer) may be deposited between the respective electrodes (e.g., electrodes 214a and 216a of FIG. 2A, electrodes 214b and 216b of FIG. 2B, or electrodes 214c and 216c of FIG. 2C) and the quantum dot layer (e.g., quantum dot layer 218a of FIG. 2A, quantum dot layer 218b of FIG. 2B, or quantum dot layer 218c of FIG. 2C) to improve carrier transport and injection. For example, in a sensor with a top electrode, a hole transport layer may be deposited between a transparent top electrode (electrically connected to electrode 216c) and the quantum dot layer 218c and an electron transport layer may be deposited between electrode 214c and the quantum dot layer 218c. In some embodiments, a graphene sheet or layer may be formed between the electrodes and the quantum dot layer to improve carrier transport. For example, a graphene sheet may be formed between the electrodes (e.g., electrodes 214a and 216a of FIG. 2A, electrodes 214b and 216b of FIG. 2B) and the quantum dot layer (e.g., quantum dot layer 218a of FIG. 2A, or quantum dot layer 218b of FIG. 2B).

At block 23, the method includes depositing a transparent dielectric layer 220c on the transparent conductive layer 219. In some embodiments, the second dielectric layer 220c is substantially the same to second dielectric layer 120a of FIG. 1C. In some embodiments, the second dielectric layer 220c is formed using the same or a substantially similar process such as described above for forming the second dielectric layer 120a in block 12a in FIG. 1C, except that the dielectric layer 220c is formed on a transparent conductive layer 219 and the dielectric layer 120a is formed on the quantum dot layer 118a. In some embodiments, the dielectric layer 220c may comprise two or more layers. For example, the second dielectric layers may comprise one or more layers of silicon oxide, silicon nitride, etc. In some embodiments, the dielectric layer(s) may be polished after deposition to form non-wavy (e.g., smooth) top surface for further deposition of other layers or devices (e.g. polymer lenses, color filters, infrared filters, etc.)

At block 24, the method includes attaching the second dielectric layer 220c to a second carrier 222 and releasing the temporary carrier 210. In some embodiments, the second dielectric layer 220c and the second carrier 222 of FIG. 2A may be similar to the second dielectric layer 120a and the second carrier 122a of FIG. 1C, and undergo similar processes for polishing the second dielectric layer 220c.

FIG. 2D schematically illustrates a method including of hybrid bonding a sensor 201c with a patterned quantum dot layer and transparent electrode with an image processor device 22, according to some embodiments. At blocks 25 and 26, the sensor 201c and the image processor device 202 are aligned, contacted, and heated to form direct interconnects 256 and 254 via hybrid bonding, such as described above (e.g., hybrid bonding method described in FIG. 1).

The method includes aligning the respective conductive features 204c and 206c of the sensor 201c to the conductive features 234 and 236 of the image processor device 202 and contacting the sensor 201c and the image processor device 202. The image processor device 202 is similar to image processor device 102a (e.g., dielectric layer 232 and conductive features 234 and 236 of image processor device 202 correspond to dielectric layer 132a and conductive features 134a and 136a of image processor device 102a).

FIG. 2E schematically illustrate example sensors 201d with a patterned quantum dot layer 218d on a semiconductor layer 270a, according to some embodiments. In some embodiments, conductive features 204d and 206d, interconnect layer 208d, interconnects 209d, insulating material 207d of FIG. 2E correspond to (e.g., is the same as or similar to) conductive features 204a and 206a, interconnect layer 208a, interconnects 209a, insulating material 207a of FIG. 2A. In some embodiments, quantum dot layer 218d and dielectric layer 220d correspond to quantum dot layer 218a and dielectric layer 220a of FIG. 2A except that the layers are processed on different substrates, e.g., a semiconductor layer 270a instead of an interconnect layer 208a. FIG. 2E may include electrode contacts 214d and 216d that are electrically connected via interconnects 209d of an interconnect layer 208d to conductive features 204d and 206d. In some embodiments, electrode contacts may be formed of a conductive material (e.g., metal, transparent conductive oxide, etc.).

The quantum dot layer 218d may act as the photodiodes (i.e. convert photons to electrical signals) and pixel transistors on the semiconductor layer 270a (e.g. silicon) may control the electrical signals. The charge created by a photo-detector (e.g., photodiode, sensor) may be converted to a voltage signal and passed on to the output amplifier through an array of row-select and column-select switches. Furthermore, an analog to digital convertor (ADC) may be formed on the semiconductor layer 270a to digitize the amplified signal. To perform readout, the pixel values of a given row may be transferred in parallel to a set of storage capacitors and then, these transferred pixel values may be read out sequentially. While the quantum dot layer 218d only perform the photodetection function, the semiconductor layer 270a may perform the rest of the operation. The semiconductor layer 270a may provide the pixel circuits comprising amp transistors, select transistors, reset transistors, signal lines, ADC., pixel select switches (or row/column selects), memory blocks, capacitors, etc. to form an image sensor circuit with the quantum dot sensor layer.

The pixel sensor architecture may be one of several types. In an active-pixel sensor (APS) architecture, each pixel location contains not only the photodiode but also an amplifier. A simpler architecture like passive-pixel sensor (PPS) may also be implemented within the semiconductor layer 270a that does not integrate an amplifier into each pixel. In a digital-pixel sensor (DPS) device architecture, each pixel may have its own analog-to-digital converter and memory block which allows the digital values proportional to light intensity.

In some embodiments, there may not be an interconnect layer 208a, electrodes may be on a top surface of the semiconductor layer 270a, the electrodes may be in contact with quantum dot layer 218d, and the electrodes may be electrically connected to conductive features 204d and 206d.

Pixel transistors may be formed on a separate semiconductor layer 270a between electrode contacts 214d and 216d and the quantum dot layer 218d. The electrodes contacts 214d and 216d may be electrically connected through the semiconductor layer 270a (e.g. using through silicon vias and plugs) to the electrodes. For example, electrodes in FIG. 2E for a quantum dot layer 218d may be similar to electrodes 214a and 216a for a quantum dot layer 218a of FIG. 2A except the electrodes are on a top surface of the semiconductor layer 270a instead of an interconnect layer 208a. Vias 272a may electrically connect the electrodes to the electrode contacts 214d and 216d, and interconnects 209d of an interconnect layer 208d may electrically connect the electrode contacts 214d and 216d to conductive features 204d and 206d. In some embodiments, the electrodes are protruded from or recessed at a top surface of the semiconductor layer 270a. In some embodiments, electrodes for a quantum dot layer 218d may be electrically connected to a pixel circuit, and an output of the pixel circuit may be electrically connected to the electrode contacts 214d and 216d.

FIG. 2F schematically illustrate example sensors 201e with a continuous quantum dot layer 218e on a semiconductor layer 270b, according to some embodiments. In some embodiments, conductive features 204e and 206e, interconnect layer 208e, interconnects 209e, insulating material 207e, and electrode contacts 214e and 216e of FIG. 2F correspond to conductive features 204d and 206d, interconnect layer 208d, interconnects 209d, insulating material 207d, and electrode contacts 214d and 216d of FIG. 2E. In some embodiments, quantum dot layer 218e and dielectric layer 220e correspond to quantum dot layer 218b and dielectric layer 220b of FIG. 2B except that the layers are processed on different substrates, e.g., a semiconductor layer 270b instead of an interconnect layer 208b.

The quantum dot layer 218e may act as the photodiodes (i.e. convert photons to electrical signals) and pixel transistors on the semiconductor layer 270b (e.g. silicon) may control the electrical signals. The charge created by a photo-detector (e.g., photodiode, sensor) may be converted to a voltage signal and passed on to the output amplifier through an array of row-select and column-select switches. Furthermore, an analog to digital convertor (ADC) may be formed on the semiconductor layer 270b to digitize the amplified signal. To perform readout, the pixel values of a given row may be transferred in parallel to a set of storage capacitors and then, these transferred pixel values may be read out sequentially. While the quantum dot layer 218e only perform the photodetection function, the semiconductor layer 270b may perform the rest of the operation. The semiconductor layer 270b may provide the pixel circuits comprising amp transistors, select transistors, reset transistors, signal lines, ADC, pixel select switches (or row/column selects), memory blocks, capacitors, etc. to form an image sensor circuit with the quantum dot sensor layer.

The pixel sensor architecture may be one of several types. In an active-pixel sensor (APS) architecture, each pixel location contains not only the photodiode but also an amplifier. A simpler architecture like passive-pixel sensor (PPS) may also be implemented within the semiconductor layer 270a that does not integrate an amplifier into each pixel. In a digital-pixel sensor (DPS) device architecture, each pixel may have its own analog-to-digital converter and memory block which allows the digital values proportional to light intensity.

In some embodiments, there may not be an interconnect layer 208b, electrodes may be on a top surface of the semiconductor layer 270b, the electrodes may be in contact with quantum dot layer 218e, and the electrodes may be electrically connected to conductive features 204e and 206e.

Pixel transistors may be formed on a separate semiconductor layer 270b between electrode contacts 214e and 216e and the quantum dot layer 218e. The electrodes contacts 214e and 216e may be electrically connected through the semiconductor layer 270b (e.g. using through silicon vias and plugs) to the electrodes. For example, electrodes in FIG. 2F for a quantum dot layer 218e may be similar to electrodes 214b and 216b for a quantum dot layer 218b of FIG. 2B except the electrodes are on a top surface of the semiconductor layer 270b instead of an interconnect layer 208b.Vias 272b may electrically connect the electrodes to the electrode contacts 214e and 216e, and interconnects 209e of an interconnect layer 208e may electrically connect the electrode contacts 214e and 216e to conductive features 204e and 206e. In some embodiments, the electrodes are protruded from or recessed at a top surface of the semiconductor layer 270b. In some embodiments, electrodes for a quantum dot layer 218e may be electrically connected to a pixel circuit, and an output of the pixel circuit may be electrically connected to the electrode contacts 214e and 216e.

In some embodiments, the electrodes comprise pairs of electrodes, and a spacing between a first pair of electrodes to a second pair of electrodes is greater than about two times a thickness of the quantum dot layer 218e. For example, minimal or no cross-talk may occur between sensor pixels if the pitch between pairs of electrodes is greater than two times the film thickness of the quantum dot layer 218e. The distance between pairs of neighboring electrodes may be about a micron or 1 or more microns apart. The thickness of the quantum dot layer 218e may be 10 nanometers, 10 or more nanometers, less than about 100 nanometers, or about 50-500 nanometers. Electrons generated by quantum dots in the quantum dot layer 218e may be collected by the closest electrode pair, and would not be collected on an adjacent pair of electrodes more than a micron away.

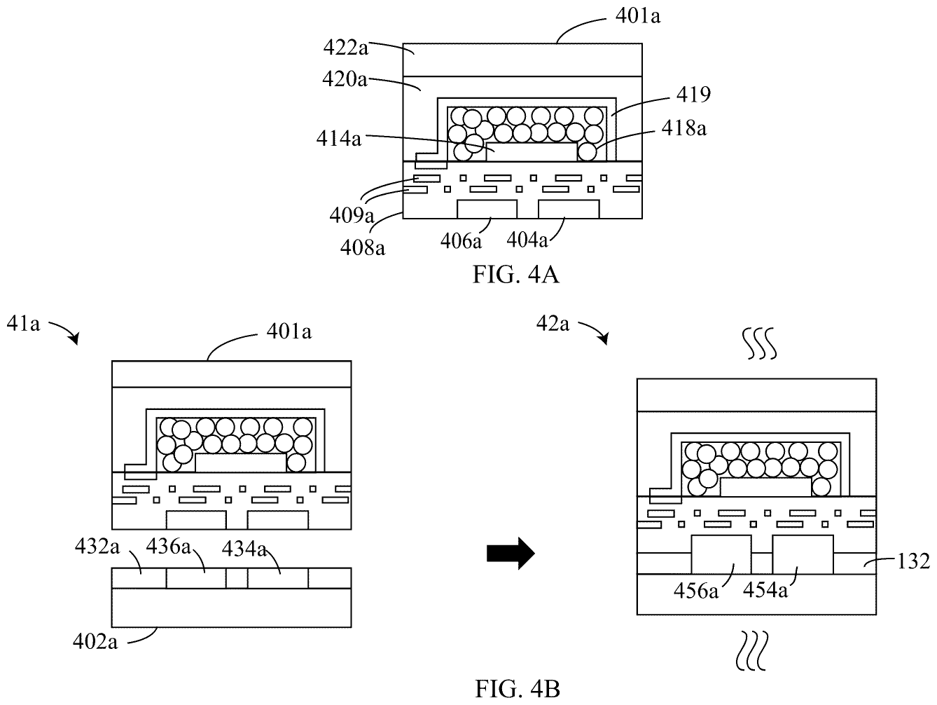

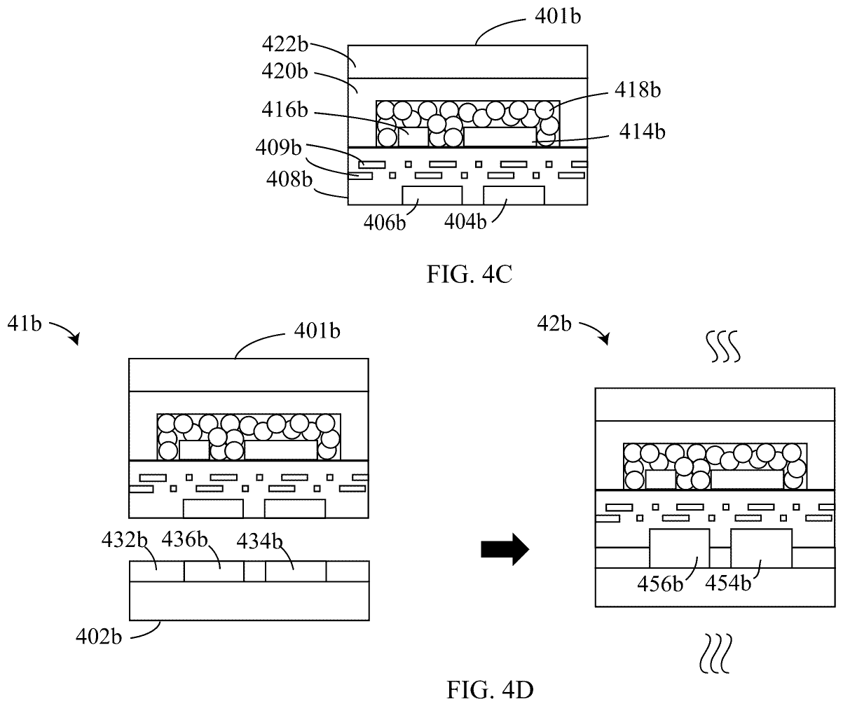

FIG. 3 schematically illustrates example configurations of electrodes, according to some embodiments. For example, the conductive features 104a or 104b and 106a or 106b of the sensor 101a or sensor 101b in FIGS. 1A-1F comprise the electrodes 301 and 302, 311 and 312, or 321 and 322 of FIG. 3. In some embodiments, the electrodes 414b and 416b of the sensor 401b of FIGS. 4C-4D comprise first and second electrodes 301 and 302, 311 and 312, or 321 and 322 of FIG. 3. In some other embodiments, only the electrodes 414a of the sensor 401a of FIG. 4A comprise first electrodes 301, 311, or 321 of FIG. 3. In some embodiments, the electrodes 414b and 416b may be planar with an interconnect layer 408b instead of protruding, or the quantum dot layer 418b may be a continuous quantum dot layer instead of patterned. The distribution of first and second electrodes of FIG. 3 may enable creation of a uniform field for carriers to move efficiently and may also reduce the distance that the carrier may cover (via hopping from one quantum dot to another quantum dot) to be eventually collected at the respective electrodes. Although a few variations of electrode placements are shown in FIG. 3, any suitable placement of electrodes and distribution of first electrodes 301 and second electrodes 302 can be provided that could generate uniform electric field to move the photogenerated carriers to respective electrode(s).

In some embodiments, the plurality of first electrodes 301 and second electrodes 302 are in a rectangular array. Each electrode may be arranged in an alternating or repeating pattern of first and second electrodes when viewed from the top down or bottom up. The first electrodes 301 may be biased with an opposite bias of the second electrodes 302. For example, first electrodes 301 may be biased with a positive bias, and the second electrodes 302 may be biased with a negative bias. In some embodiments, the first electrodes 301 are electrically connected to a first conductive feature 204a or 204b, and the second electrodes 302 are electrically connected to a second conductive feature 206a or 206b through interconnects 209a or 209b in an interconnect layer 208a or 208b, so that each conductive feature is connected to a plurality of electrodes. In this way, a uniform period distribution of electrodes may create a uniform field for carriers to move efficiently. Any suitable number of first electrodes 301 and second electrodes 302 may be used (one or more first electrodes 301 and/or one or more second electrodes 302) and can be formed in any uniform or non-uniform distribution.

In some embodiments the pitch or separation between one of the first electrodes 301 and neighboring one of the second electrodes 302 may be comparable to the thickness of the quantum dot layer. For example, if the thickness of the quantum dot layer is 50 nm, the electrodes 301 and 302 may have a separation of 10 nm-100 nm between them and pixel size may be substantially larger (e.g. 0.5-5 μm).

In some embodiments, the first electrode 311 and the second electrode 312 are interdigitated electrodes. The first electrode 311 may be biased with an opposite bias of the second electrode 312. The first electrode 311 may be biased with a positive bias, and the second electrode may be biased with a negative bias. In some embodiments the pitch or separation between first electrodes 311 and second electrodes 312 may be comparable to the thickness of the quantum dot layer.

In some embodiments, one or more first electrodes 321 and one or more second electrodes 322 are in a shape of concentric rings. The first electrode 321 may be biased with an opposite bias of the second electrodes 322. The first electrode 321 may be biased with a positive bias, and the second electrode 322 may be biased with a negative bias.

In FIG. 3, one first electrode 321 and two second electrodes 322 are shown. In some embodiments, the first electrode 321 is electrically connected to the first conductive feature 204a or 204b and the two second electrodes 322 are electrically connected to the second conductive feature 206a or 206b. However, any suitable number of first electrodes 321 and second electrodes 322 may be used (one or more first electrodes 321 and/or one or more second electrodes 322) and can be formed in any uniform or non-uniform distribution. In some embodiments the separation between one of the first electrodes 321 and one of the second electrodes 322 may be comparable to the thickness of the quantum dot layer.

FIG. 4A schematically illustrates an example of a sensor 401a with a patterned quantum dot layer 418a and a protruding electrode 414a, according to some embodiments. The sensor 401a is similar to the sensor 201b of FIG. 2B except the first electrode 414a is protruding from a surface of the interconnect layer 408a instead of the first electrode 214b being planar with a surface of the interconnect layer 208b. The interconnect layer 408a of FIG. 4A may be similar to the interconnect layer 208a of FIG. 2A. The transparent interconnects 409a, conductive features 404a and 406a, and dielectric layer 422a may correspond to interconnects 209a, conductive features 204a and 206a, and dielectric layer 220a of FIG. 2A. In some embodiments, the interconnects 409a may not be transparent.

In FIG. 4A, the protruding electrodes 414a is shown to be on a surface of the interconnect layer 408a. However, in some embodiments a portion of the electrodes 414a may be in the interconnect layer 408a and another portion of the electrodes 414a may be protruding out of a surface of the interconnect layer 408a (e.g., combining electrode 214c of FIG. 2C and electrode 414b of FIG. 4C). In some embodiments, electrodes 414a and 419 may correspond to conductive features 404a and 406a. In some embodiments, the conductive features 404a and 406a may be spaced or sized differently. In some embodiments, a conductive feature may correspond to an electrode of a pixel. In some embodiments, a conductive feature may correspond to electrodes of multiple pixels.

FIG. 4B schematically illustrates a method of hybrid bonding a sensor 401a with a patterned quantum dot layer 418a and a protruding electrode 414a to an image processor device 402a, according to some embodiments. At blocks 41a and 42a, the sensor 401a and the image processor device 402a are aligned, contacted, and heated to form direct interconnects 456a and 454a via hybrid bonding, such as the hybrid bonding method described above. The method includes aligning the respective conductive features 404a and 406a of the sensor 401a to the conductive features 434a and 436a of the image processor device 402a and contacting the sensor 401a and the image processor device 402a. The image processor device 402a is similar to image processor device 102a (e.g., dielectric layer 432a and conductive features 434a and 436a of image processor device 402a correspond to dielectric layer 132a and conductive features 134a and 136a of image processor device 102a).

FIG. 4C schematically illustrates an example of a sensor 401b with a patterned quantum dot layer 418b and protruding electrodes 414b and 416b, according to some embodiments. The sensor 401a is similar to the sensor 401a of FIG. 4A except that sensor 401a does not include a transparent conductive layer or top electrode 419, and both electrodes 414b and 416b protrude from a surface of the interconnect layer 408b into the quantum dot layer 418b instead of only electrode 414a protruding.

In FIG. 4C, the protruding electrodes 414b and 416b are shown to be on a surface of the interconnect layer 408b. However, in some embodiments a portion of the electrodes 414b and 416b may be in the interconnect layer 408b and another portion of the electrodes 414b and 416b may be protruding out of a surface of the interconnect layer 408b (e.g., combining electrodes 216a and 214a of FIG. 2A and electrodes 414b and 416b of FIG. 4C).

FIG. 4D schematically illustrates a method of hybrid bonding a sensor 401b with a patterned quantum dot layer 418b and protruding electrodes 414b and 416b, according to some embodiments. At blocks 41b and 42b, the sensor 401a and the image processor device 402b are aligned, contacted, and heated to form direct interconnects 456b and 454b via hybrid bonding, such as the hybrid bonding method described above. The method includes aligning the respective conductive features 404b and 406b of the sensor 401b to the conductive features 434b and 436b of the image processor device 402b and contacting the sensor 401b and the image processor device 402b. The image processor device 402b is similar to image processor device 102b (e.g., dielectric layer 432b and conductive features 434b and 436b of image processor device 402b correspond to dielectric layer 132b and conductive features 134b and 136b of image processor device 102b).

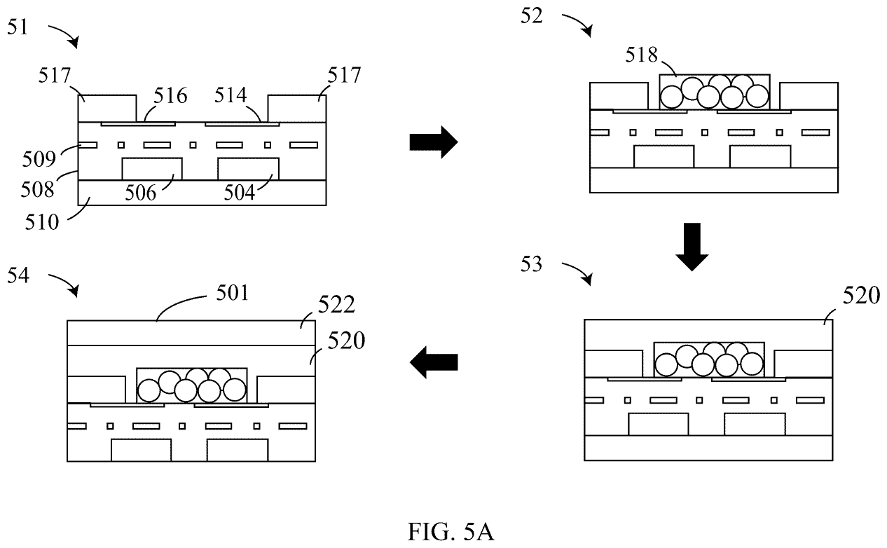

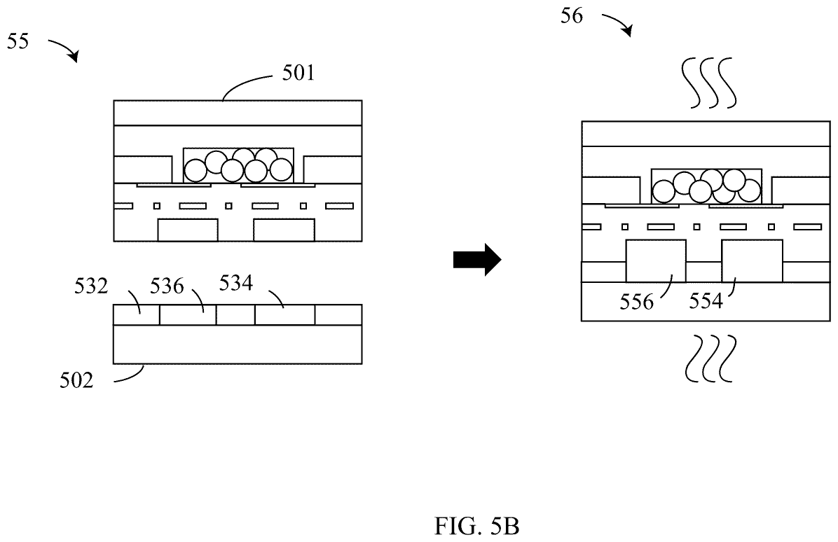

FIG. 5A schematically illustrates a method of forming a device with a patterned quantum dot layer and a pair of recessed electrodes, according to some embodiments. At block 51, a substrate comprises a first dielectric layer 517, electrodes 514 and 516, an interconnect layer 508, and conductive features 504 and 506. The substrate is attached to a temporary carrier 510. The temporary carrier 510 may be another substrate (e.g., glass or a semiconductor wafer). The interconnect layer 508 of FIG. 5A may be similar to the interconnect layer 208a of FIG. 2A. The interconnect layer 508 may comprise interconnects 509 disposed in an insulating material. The electrodes 514 and 516 are recessed from a surface of the first dielectric layer 517. The electrodes 514 and 516 are electrically connected to the conductive features 504 and 506, via interconnects 509 in the interconnect layer 508. In some embodiments, the recessed electrodes 514 and 516 may also be arranged in the repetitive pattern described in FIG. 3.

The first dielectric layer 517 may be similar to the first dielectric layer 112a of FIG. 1C, except electrodes are exposed through the first dielectric layer 517 instead of being disposed in the first dielectric layer 112a. The first dielectric layer 517 may be one or more layers of an oxide or a nitride material (e.g. silicon oxide, silicon nitride, etc.). The thickness of the first dielectric layer 517 may be about hundreds of nanometers in thickness (e.g., 100, 200 nm, or above 200 nm) or may be tens of nanometers in thickness (e.g., 10, 20 nm, or above 20 nm).

At block 52, the method includes depositing a quantum dot layer 518 on at least a portion of the electrodes 514 and 516. The quantum dot layer 518 is patterned, and may be patterned using processes described above for patterning a quantum dot layer. In some embodiments, the quantum dot layer 518 may be deposited by ink jet printing in which a certain amount of quantum dot material (e.g. size, shape, volume, material type, etc.) may be directly deposited to pixel locations to form individual pixels.

At block 53, the method includes depositing a second dielectric layer 520. The second dielectric layer 520 may be similar to the second dielectric layer 120a in FIG. 1C and may be formed using a same or a substantially similar process, except it is deposited over a patterned quantum dot layer 518, exposed portions of the electrodes 514 and 516, and portions of a surface of the interconnect layer 508. In some embodiments, a patterned quantum dot layer 518 may cover the exposed portions of the electrodes 514 and 516, and the dielectric layer 520 may be deposited over a quantum dot layer and portions of a surface of the interconnect layer 508. In some embodiments, a quantum dot layer may not be patterned, and the dielectric layer 520 may be deposited over a continuous quantum dot layer. In some embodiments, the second dielectric layer 520 may be a transparent layer.

At block 54, the method includes attaching the second dielectric layer 520 to a second carrier 522 and releasing the temporary carrier 510. In some embodiments, the second carrier 522 may be substantially the same to the second carrier 122a of FIG. 1C. In some embodiments, the second dielectric layer 520 is polished before attaching to the second carrier 522.

FIG. 5B schematically illustrates a method of hybrid bonding a sensor 501 with a patterned quantum dot layer 518 and a pair of recessed electrodes 514 and 516 to an image processor device 502, according to some embodiments. At blocks 55 and 56, the sensor 501 and the image processor device 502 are aligned, contacted, and heated to form direct interconnects 556 and 554 via hybrid bonding, such as the hybrid bonding method described above. The method includes aligning the respective conductive features 504 and 506 of the sensor 501 to the conductive features 534 and 536 of the image processor device 502 and contacting the sensor 501 and the image processor device 502. The image processor device 502 is similar to image processor device 102a (e.g., dielectric layer 532 and conductive features 534 and 536 of image processor device 502 correspond to dielectric layer 132a and conductive features 134a and 136a of image processor device 102a).

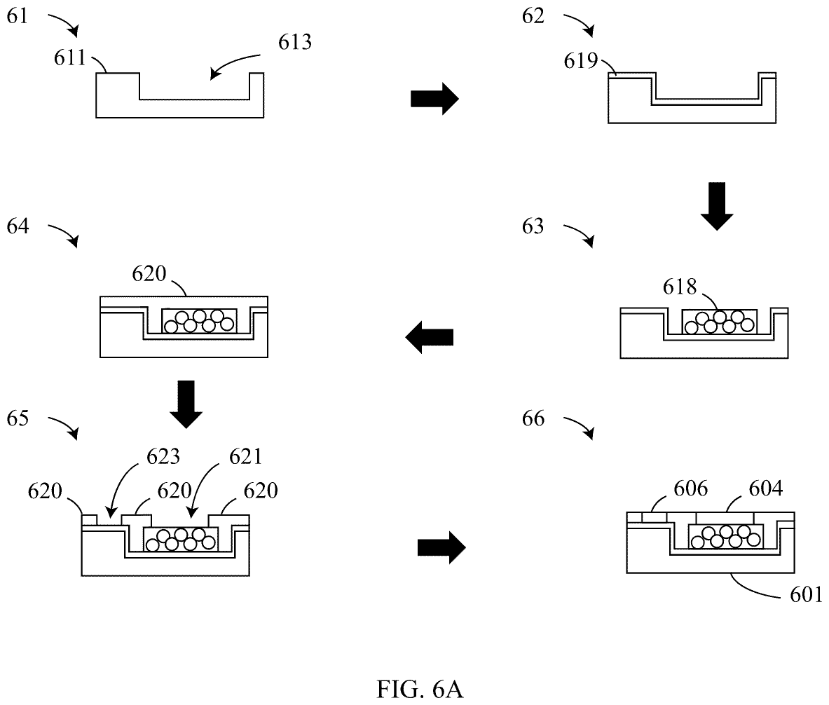

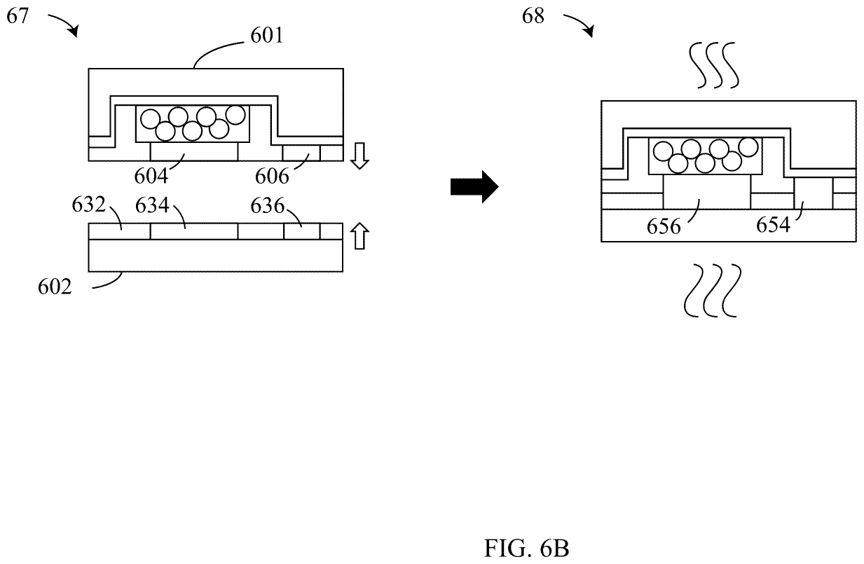

FIG. 6A schematically illustrates a method of forming a sensor 601 with a patterned quantum dot layer 618 and transparent electrode 619, according to some embodiments. At block 61, a substrate 611 includes an opening 613 in the substrate 611. In some embodiments, substrate 611 includes a transparent substrate (e.g. glass or silicon oxide and/or silicon nitride on another temporary substrate). The opening 613 may have a depth of about few nanometers or tens of nanometers (e.g., 5, 10, 20 nm, or above 20 nm) to hundreds of nanometers (e.g., 100, 200 nm, or above 200 nm).

At block 62, the method includes depositing a transparent conductive layer 619 (e.g., ITO) on the substrate 611. In some embodiments, the method may begin at block 62, where a transparent conductive layer 619 is in the opening 613 of the substrate 611.

At block 63, the method includes depositing a quantum dot layer 618 on the transparent conductive layer 619 in the opening 613 of the substrate 611. The quantum dot layer 618 is patterned, and may be patterned using processes described above for patterning a quantum dot layer. In some embodiments, the quantum dot layer 618 may be deposited by ink jet printing in which a certain amount of quantum dot material may be directly deposited to form individual pixels.

At block 64, the method includes depositing a dielectric layer 620. The dielectric layer 620 may comprise organic material (e.g. PI, PBO, BCB, etc.) or inorganic material (e.g. silicon oxide) or a combination of them. The dielectric layer 620 covers the patterned quantum dot layer 618 and portions of surfaces of the transparent conductive layer 619 (e.g., surfaces not covered by the patterned quantum dot layer 618).

At block 65, the method includes patterning the dielectric layer 620 to form a first opening 621 in the dielectric layer 620 to expose a portion of the quantum dot layer 618, and a second opening 623 in the dielectric layer 620 to expose a portion of the transparent conductive layer 619.

At block 66, the method includes depositing a conductive layer in the first opening 621 and the second opening 623 to form conductive features. A first conductive feature 604 is formed in the first opening 621, and a second conductive feature 606 is formed in the second opening 623. The second conductive feature 606 is electrically connected to the transparent conductive layer 619. In some embodiments, the method includes depositing a layer of conductive material on the dielectric layer 620 patterned to expose portions of the quantum dot layer 618, and removing an overburden of the conductive material using a CMP process. In some embodiments, one or more interconnect layers or redistribution layers may be formed before forming the conductive features 604 and 606. For example, after the quantum dot layer 618 is formed, one or more interconnect layers or redistribution layers are formed.

FIG. 6B schematically illustrates a method of hybrid bonding a sensor 601 with a patterned quantum dot layer and transparent electrode with an image processor device 602, according to some embodiments. At blocks 67 and 68, the sensor 601 and the image processor device 602 are aligned, contacted, and heated to form direct interconnects 656 and 654 via hybrid bonding, such as the hybrid bonding method described above. The method includes aligning the respective conductive features 604 and 606 of the sensor 601 to the conductive features 634 and 636 of the image processor device 602 and contacting the sensor 601 and the image processor device 602. The image processor device 602 is similar to image processor device 102a (e.g., dielectric layer 632 and conductive features 634 and 636 of image processor device 602 correspond to dielectric layer 132a and conductive features 134a and 136a of image processor device 102a).

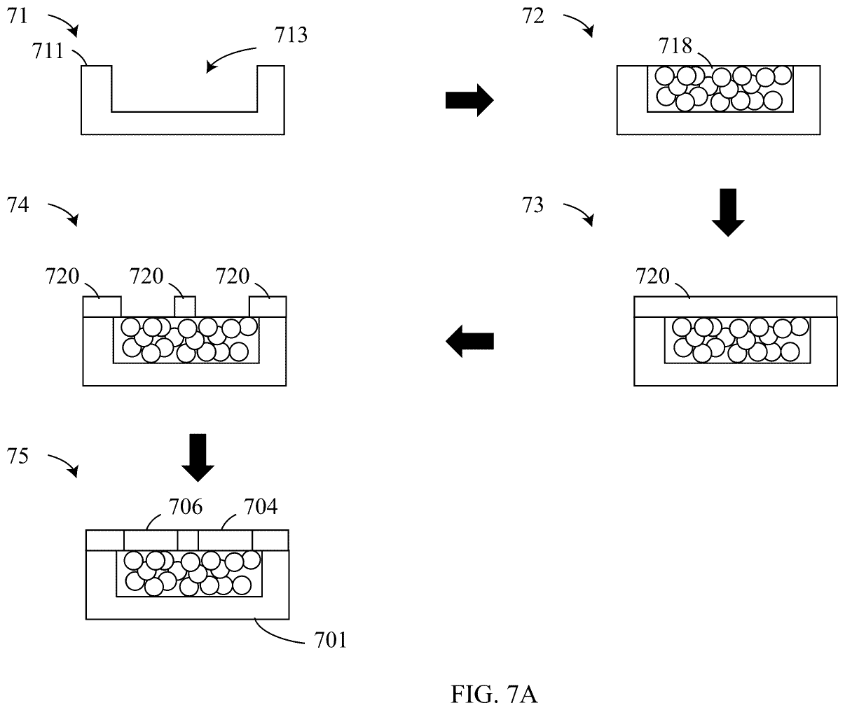

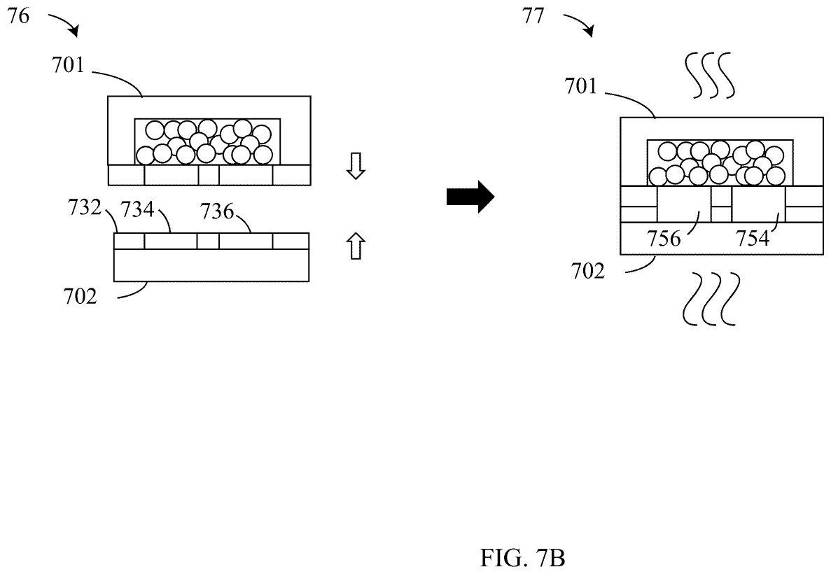

FIG. 7A schematically illustrates a method of forming a sensor 701 with a patterned or printed quantum dot layer 718, according to some embodiments. At block 71, a substrate 711 includes an opening 713. At block 72, the method includes depositing a quantum dot layer 718 in an opening 713 of the substrate 711. At block 73, the method includes depositing a dielectric layer 720 on the substrate 711. At block 74, the dielectric layer 720 is patterned to expose portions of the quantum dot layer 718. At block 75, the method includes depositing conductive features 704 and 706 on the substrate 711. The conductive features 704 and 706 may be formed on the exposed portions of the quantum dot layer 718. In some embodiments, the method includes depositing a layer of conductive material on the dielectric layer 720 patterned to expose portions of the quantum dot layer 718, and removing an overburden of the conductive material using a CMP process. In some embodiments, one or more interconnect layers or redistribution layers may be formed before forming the conductive features 704 and 706. For example, after the quantum dot layer 718 is formed, one or more interconnect layers or redistribution layers are formed.

FIG. 7B schematically illustrates a method of hybrid bonding a sensor 701 with a patterned quantum dot layer 718 to an image processor device 702, according to some embodiments. At blocks 76 and 77, the sensor 701 and the image processor device 702 are aligned, contacted, and heated to form direct interconnects 756 and 754 via hybrid bonding, such as the hybrid bonding method described above. The method includes aligning the respective conductive features 704 and 706 of the sensor 701 to the conductive features 734 and 736 of the image processor device 702 and contacting the sensor 701 and the image processor device 702. The image processor device 702 is similar to image processor device 102a (e.g., dielectric layer 732 and conductive features 734 and 736 of image processor device 702 correspond to dielectric layer 132a and conductive features 134a and 136a of image processor device 102a).

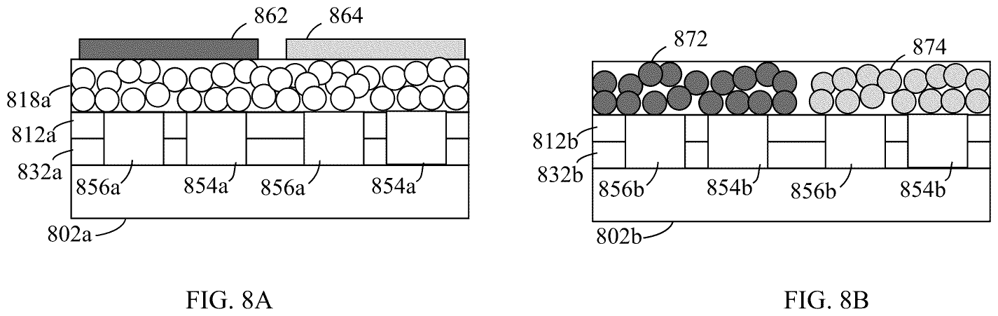

FIG. 8A schematically illustrates an image sensor device with color filters, according to some embodiments. The image sensor device comprises a sensor that is hybrid bonded to an image processor device 802a. In some embodiments, the sensor shown in FIG. 8A is similar to the sensor 101b formed in FIG. 1D except the sensor does not include a second dielectric layer 120b and a second carrier 122b, and the sensor includes color filter layers 862 and 864 on a quantum dot layer 818a. The quantum dot layer 818a may be similar to quantum dot layer 118b of FIG. 1D, and may be processed using similar processes and formed on a substrate comprising a dielectric layer 112a and conductive features 104a and 106a disposed in the dielectric layer 112a. The sensor 801a and the image processor device may be attached to one another through direct bonds formed between the dielectric layers 812a and 832a without the use of an intervening adhesive. The sensor and the image processor device 802a may be aligned, contacted, and heated to form direct interconnects 856a and 854a via hybrid bonding, such as the hybrid bonding method described above. The image sensor device may include sensor of a first type and a sensor of a second type. The sensor may comprise a same type of quantum dot layer 818a but a different type of color filter layers 862 and 864. For example, the quantum dot layer may be fabricated and tuned to absorb the light in the visible spectrum (e.g. 400 nm-790 nm) and the color filter layer 862 may be a green color filter (e.g., enabling wavelengths of a green color to pass through, around 495-570 nm), and the color filter layer 864 may be a red color filter (e.g., enabling wavelengths of a red color to pass through, around 620-750 nm).

FIG. 8B schematically illustrates an image sensor device with a patterned or printed quantum dot layer with different quantum dots 872 and 874, according to some embodiments. The image sensor device comprises a sensor that is hybrid bonded to an image processor device 802b. The sensor of FIG. 8B includes a patterned quantum dot layer with different quantum dots, such as quantum dots 872 and quantum dots 874. A different type of quantum dots are formed on sets of electrodes. For example, a patterned quantum dot layer with quantum dots 872 is formed on a first set of electrodes to form a first sensor pixel, and a patterned quantum dot layer with quantum dots 874 is formed on a second set of electrodes to form a second sensor pixel. For example, quantum dots 872 may absorb wavelengths of a green color, and quantum dots 874 may absorb wavelengths of a red color. In another embodiment, quantum dots 872 that absorb wavelengths of a green color are placed or deposited (e.g. using inkjet printing, precision screen printing, nanoimprint technology) first and then quantum dots 874 that absorb wavelengths of a red color are placed or deposited at their location on the pixel. The sensor 801a and the image processor device may be attached to one another through direct bonds formed between the dielectric layers 812b and 832b without the use of an intervening adhesive. The sensor and the image processor device 802b may be aligned, contacted, and heated to form direct interconnects 856b and 854b via hybrid bonding, such as the hybrid bonding method described above. The image sensor device may include sensors of a first type or a second type. The first type of sensor may comprise quantum dots 872 and the second type of sensor may comprise quantum dots 874.

In some embodiments, the quantum dot layer is formed on the surface of the substrate using Zi bonds. A surface of the substrate is activated. For example, a surface of the dielectric layer (and electrodes or conductive features) may be activated using hydrogen plasma. The quantum dots may deposited on the surface via a fluid carrier or using a nitrogen or argon carrier. For example, a quantum dot solution may be spray coated using pressurized gas. The quantum dots are attracted to the activated surface, and coat the surface by attaching to the activated surface with Zi bonds. The quantum dots may coat the surface uniformly, and the excess quantum dots may that are not bonded to the surface of the substrate be removed by shaking or blowing off the substrate. The substrate may be heated, and temperature may be increased to increase the bond strength of the quantum dots. After the quantum dot layer is formed, the quantum dot layer may be coated by a dielectric layer. The dielectric layer may be planarized.

In some embodiments, multiple activation of a surfaces may be used to form multiple quantum dot layers. For example, a surface may be activated and coated with quantum dots to form a quantum dot layer, and an activation may be performed on the surface of the deposited quantum dot layer to form a second quantum dot layer. The process may be repeated (e.g. 2 or more layer, 30-40 layers). The substrate may be heated, and the temperature may be increased to increase the bond strength of the quantum dots. After the multiple quantum dot layers are formed, the last or final layer of multiple quantum dot layers can be coated by the dielectric and the dielectric layer may be planarized.

It is contemplated that any combination of the methods described above may be used to form the sensor for bonding whether or not expressly recited herein.

The embodiments discussed above are intended to be illustrative and not limiting. One skilled in the art would appreciate that individual aspects of the devices and methods discussed herein may be omitted, modified, combined, and/or rearranged without departing from the scope of the claimed subject matter. Only the claims that follow are meant to set bounds as to what the claimed subject matter includes.

1-2. (canceled)

3. A method of forming an image sensor device, the method comprising:
forming a sensor, comprising:
depositing a quantum dot layer on a first electrode of a substrate, the substrate comprising:
electrodes comprising the first electrode and a second electrode;
an interconnect layer; and
conductive features comprising a first conductive feature and a second conductive feature, wherein the first electrode and the second electrode are electrically connected to the first conductive feature and the second conductive feature, respectively via interconnects in the interconnect layer;
depositing a transparent conductive layer on the quantum dot layer and the second electrode, wherein the transparent conductive layer is electrically connected to the second electrode; and
hybrid bonding the sensor to an image processor device without use of an intervening adhesive to connect the conductive features of the sensor to conductive features of the image processor device.

4. The method of claim 3, further comprising:
depositing a dielectric layer on the transparent conductive layer.

5. The method of claim 3, wherein the first electrode is planar with a surface of the interconnect layer.

6. The method of claim 3, wherein the first electrode protrudes from a surface of the interconnect layer.

7-14. (canceled)

15. The method of claim 3, wherein the depositing the quantum dot layer is performed by ink jet printing.

16. The method of claim 3, wherein the depositing the quantum dot layer is performed by spin coating.

17. (canceled)

18. The method of claim 3, wherein the depositing the quantum dot layer comprises:
spin coating to form a spin coated quantum dot layer; and
patterning the spin coated quantum dot layer.

19-24. (canceled)

25. The method of claim 3, wherein the sensor is of a first type or a second type, wherein the first type of sensor and the second type of sensor comprises a same type of quantum dot layer but a different type of color filter layer.

26. The method of claim 3, wherein the sensor is of a first type or a second type, wherein the first type of sensor comprises a different type of quantum dot layer than the second type of sensor.

27-28. (canceled)

29. An image sensor device comprising:
a sensor comprising:
a quantum dot layer on a first electrode of a substrate, the substrate comprising:
electrodes comprising the first electrode and a second electrode;
an interconnect layer; and
conductive features comprising a first conductive feature and a second conductive feature, wherein the first electrode and the second electrode are electrically connected to the first conductive feature and the second conductive feature, respectively via interconnects in the interconnect layer;
a transparent conductive layer on the quantum dot layer and the second electrode, wherein the transparent conductive layer is electrically connected to the second electrode; and
an image processor device, wherein the sensor is hybrid bonded to the image processor device without use of an intervening adhesive to connect the conductive features of the sensor to conductive features of the image processor device.

30. The image sensor device of claim 29, further comprising:
a dielectric layer on the transparent conductive layer.

31. The image sensor device of claim 29, wherein the first electrode is planar with a surface of the interconnect layer.

32. The image sensor device of claim 29, wherein the first electrode protrudes from a surface of the interconnect layer.

33-42. (canceled)

43. The image sensor device of claim 29, wherein the quantum dot layer is ink jet printed.

44. The image sensor device of claim 29, wherein the quantum dot layer is spin coated.

45. The image sensor device claim 29, wherein:
the conductive features of the sensor comprise pairs of electrodes;
the quantum dot layer is spin coated to form a continuous quantum dot layer; and
a spacing between a first pair of electrodes to a second pair of electrodes is greater than about two times a thickness of the quantum dot layer.

46. The image sensor device of claim 29, wherein the quantum dot layer is spin coated and then patterned.

47-52. (canceled)

53. The image sensor device of claim 29, wherein the sensor is of a first type or a second type, wherein the first type of sensor and the second type of sensor comprises a same type of quantum dot layer but a different type of color filter layer.

54. The image sensor device of claim 29, wherein the sensor is of a first type or a second type, wherein the first type of sensor comprises a different type of quantum dot layer than the second type of sensor.

55-56. (canceled)
